(19) United States
(12) Patent Application Publication
(10) Pub. No.: US 2024/0055297 A1
(43) Pub. Date: Feb. 15, 2024

(54) MANUFACTURING METHOD OF SEMICONDUCTOR

(71) Applicant: Fu-chiang LIAO, Taoyuan City (TW)

(72) Inventor: Fu-chiang LIAO, Taoyuan City (TW)

(21) Appl. No.: 18/366,708

(22) Filed: Aug. 8, 2023

(30) Foreign Application Priority Data
Aug. 10, 2022 (CN) 202210955004.X

(51) Int. Cl. H01L 21/78; H01L 21/56

(52) U.S. Cl. CPC H01L 21/78; H01L 21/561

(57) ABSTRACT

A manufacturing method of a semiconductor includes steps of (a) providing a semiconductor substrate having a front side and a back side, (b) adhering a back protection film on the back side, (c) cutting the semiconductor substrate to a set depth along a plurality of cutting paths from the front side to form a plurality of scribing lines and separate a plurality of dies by the scribing lines, (d) adhering a front protection film on the front side, (e) removing the back protection film, (f) grinding the semiconductor substrate from the back side until a remaining thickness of the semiconductor substrate equals to the set depth to expose the dies and the scribing lines, and (g) performing an evaporation to the semiconductor substrate to attach a plurality of metal particles to the dies. Therefore, the efficiency of heat-dissipation is effectively enhanced because of the distribution of the metal particles.

### FIELD OF INVENTION

The present invention relates to a manufacturing method, and more particularly to a manufacturing method of a semiconductor effectively facilitating the efficiency of heat-dissipation.

### BACKGROUND OF DISCLOSURE

In the conventional semiconductor process, the heat-dissipation of power chips is usually achieved by coating the back of the wafer with metal.

In specific, a film is firstly adhered on a front surface of a wafer in a general process, and then a back surface of the wafer is grinded for thinning. After the processes of removing the stress, cleaning, removing the oxide layer and drying, a vaporizer is used to vaporize the metal on the back surface of the wafer, followed by adhering a film on the back surface of the wafer and peeling the film off the front surface of the wafer, then cutting and encapsulating the wafer with a metal frame, so that the chips are finally manufactured. The main heat-dissipation path is through the metal coated on the bottom of the wafer, which facilitates the heat-dissipation by connecting with the metal frame.

However, this manufacturing method of grinding the wafer before cutting is only applicable to products with thicker thicknesses, such as power chips with a final thickness of about 250 micrometers. If this traditional manufacturing method is applied to products with thinner thicknesses, wafer warpage or even breakage often occurs during the production process, making manufacturing difficult and adding many additional costs.

Therefore, there is a need to provide a manufacturing method of a semiconductor to solve the problems of prior art.

### SUMMARY OF INVENTION

The motive of the present invention is to provide a manufacturing method of a semiconductor, which intends to solve and improve the above-mentioned problems and drawbacks of prior art.

The main purpose of the present invention is to provide a manufacturing method of a semiconductor. By adhering a back protection film on a back side of a semiconductor substrate and cutting the semiconductor substrate to a set depth from a front side firstly, and then adhering a front protection film on the front side of the semiconductor substrate and grinding the semiconductor substrate from the back side, the back side of the semiconductor substrate is protected from the risk of breaking during cutting. It also prevents the warpage of the semiconductor substrate. Further, by exposing the dies and the scribing lines and performing an evaporation, the metal particles are deeply distributed in the scribing lines and attached around the dies. The efficiency of heat-dissipation can be effectively increased.

In accordance with an aspect of the present invention, there is provided a manufacturing method of a semiconductor, comprising steps of: (a) providing a semiconductor substrate having a front side and a back side; (b) adhering a back protection film on the back side; (c) cutting the semiconductor substrate to a set depth along a plurality of cutting paths from the front side to form a plurality of scribing lines and separate a plurality of dies by the scribing lines; (d) adhering a front protection film on the front side; (e) removing the back protection film; (f) grinding the semiconductor substrate from the back side until a remaining thickness of the semiconductor substrate equals to the set depth to expose the dies and the scribing lines; and (g) performing an evaporation to the semiconductor substrate to attach a plurality of metal particles to the dies.

In an embodiment of the present invention, each of the dies comprises a first surface and a second surface disposed opposite to each other and a third surface, a fourth surface, a fifth surface, and a sixth surface perpendicular to the first surface and the second surface, and the metal particles are attached on the second surface, the third surface, the fourth surface, the fifth surface, and the sixth surface.

In an embodiment of the present invention, the metal particles are a plurality of titanium-nickel-silver particles.

In an embodiment of the present invention, the set depth is in a range between 37.5 μm and 150 μm.

In an embodiment of the present invention, the scribing lines each has a width equal to 40 μm, and the metal particles each has a particle diameter equal to 1 μm.

In an embodiment of the present invention, a thickness of the back protection film is 90 μm, and in the step (c), a thickness of the semiconductor substrate is 300 μm.

In an embodiment of the present invention, the set depth is 70 μm, the step (c) is implemented by a blade of a wafer cutting machine, and a blade height parameter of the blade is 320 μm.

In an embodiment of the present invention, the manufacturing method of a semiconductor further comprises steps, between the step (f) and step (g), of: (f1) removing residual stresses from the semiconductor substrate; (f2) cleaning the semiconductor substrate; (f3) removing an oxide layer of the semiconductor substrate; and (f4) drying the semiconductor substrate.

In an embodiment of the present invention, the manufacturing method of a semiconductor further comprises steps, after the step (g), of: (h) adhering a second back protection film on the back side; (i) removing the front protection film; and (j) performing an encapsulation to the semiconductor substrate.

In an embodiment of the present invention, in the step (j), the dies are encapsulated to form a plurality of power chips.

### BRIEF DESCRIPTION OF DRAWINGS

FIG. 1 schematically illustrates a flowchart of a manufacturing method of a semiconductor according to an embodiment of the present invention;

FIG. 2 schematically illustrates a semiconductor substrate, a back protection film, and the cutting of the semiconductor substrate in a manufacturing method of a semiconductor according to an embodiment of the present invention;

FIG. 3 schematically illustrates a perspective view of cutting a semiconductor substrate attached with a back protection film and scribing lines and dies in a manufacturing method of a semiconductor according to an embodiment of the present invention;

FIG. 4 schematically illustrates a semiconductor substrate, scribing lines, dies, and a back protection film in a manufacturing method of a semiconductor according to an embodiment of the present invention;

FIG. 5 schematically illustrates a front protection film, a semiconductor substrate, and the grinding of the semiconductor substrate from a back side in a manufacturing method of a semiconductor according to an embodiment of the present invention;

FIG. 6 schematically illustrates a front protection film, a remaining thickness of the semiconductor substrate equal to a set depth, and the evaporation of the semiconductor substrate from a back side in a manufacturing method of a semiconductor according to an embodiment of the present invention;

FIG. 7 schematically illustrates a perspective view of a die and the distribution of metal particles after the evaporation of a manufacturing method of a semiconductor according to an embodiment of the present invention;

FIG. 8 schematically illustrates an inverted perspective view of the die shown in FIG. 7 and the distribution of metal particles;

FIG. 9 schematically illustrates a front protection film, a semiconductor substrate, and a second back protection film in a manufacturing method of a semiconductor according to an embodiment of the present invention;

FIG. 10 schematically illustrates a semiconductor substrate and a second back protection film in a manufacturing method of a semiconductor according to an embodiment of the present invention;

FIG. 11 schematically illustrates a detailed flowchart of a manufacturing method of a semiconductor according to an embodiment of the present invention;

FIG. 12 schematically illustrates a semiconductor substrate, a back protection film, and the cutting of the semiconductor substrate in a manufacturing method of a semiconductor according to another embodiment of the present invention;

FIG. 13 schematically illustrates a perspective view of cutting a semiconductor substrate attached with a back protection film and scribing lines and dies in a manufacturing method of a semiconductor according to another embodiment of the present invention;

FIG. 14 schematically illustrates a semiconductor substrate, scribing lines, dies, and a back protection film in a manufacturing method of a semiconductor according to another embodiment of the present invention;

FIG. 15 schematically illustrates a front protection film, a semiconductor substrate, and the grinding of the semiconductor substrate from a back side in a manufacturing method of a semiconductor according to another embodiment of the present invention;

FIG. 16 schematically illustrates a front protection film, a remaining thickness of the semiconductor substrate equal to a set depth, and the evaporation of the semiconductor substrate from a back side in a manufacturing method of a semiconductor according to another embodiment of the present invention;

FIG. 17 schematically illustrates a perspective view of a die and the distribution of metal particles after the evaporation of a manufacturing method of a semiconductor according to another embodiment of the present invention;

FIG. 18 schematically illustrates an inverted perspective view of the die shown in FIG. 17 and the distribution of metal particles;

FIG. 19 schematically illustrates a front protection film, a semiconductor substrate, and a second back protection film in a manufacturing method of a semiconductor according to another embodiment of the present invention; and

FIG. 20 schematically illustrates a semiconductor substrate and a second back protection film in a manufacturing method of a semiconductor according to another embodiment of the present invention.

### DETAILED DESCRIPTION OF PREFERRED EMBODIMENTS

The structure and the technical means adopted by the present disclosure to achieve the above and other objects can be best understood by referring to the following detailed description of the preferred embodiments and the accompanying drawings. Furthermore, directional terms described by the present disclosure, such as upper, lower, top, bottom, front, back, left, right, inner, outer, side, peripheral, central, horizontal, vertical, longitudinal, axial, radial, and etc., are only directions by referring to the accompanying drawings, and thus the used directional terms are used to describe and understand the present disclosure, but the present disclosure is not limited thereto.

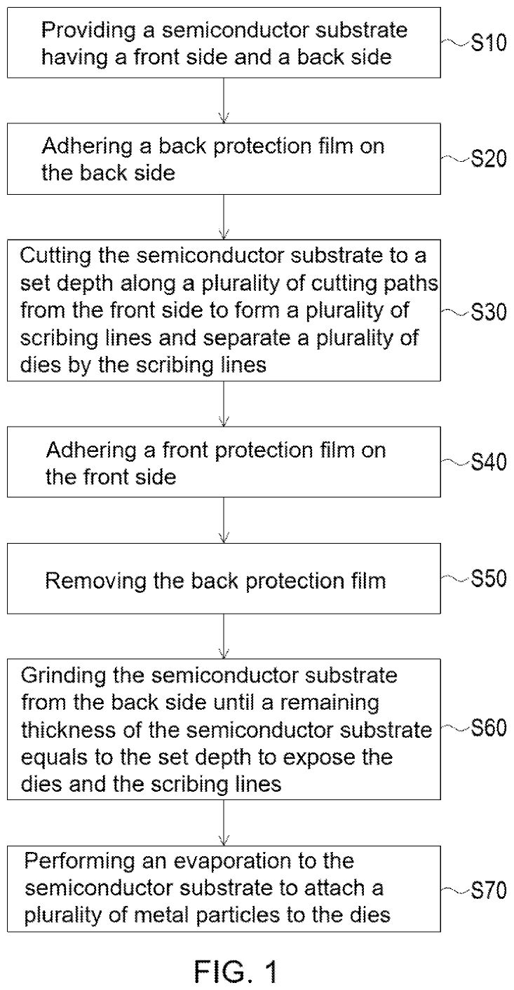

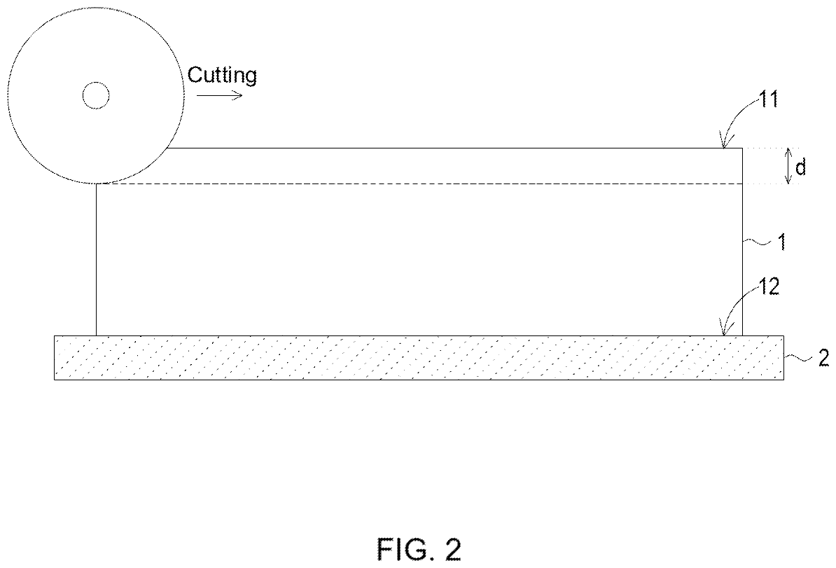

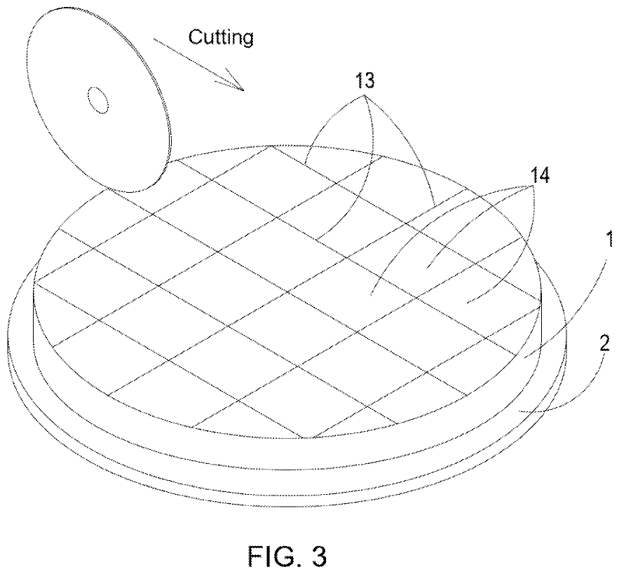

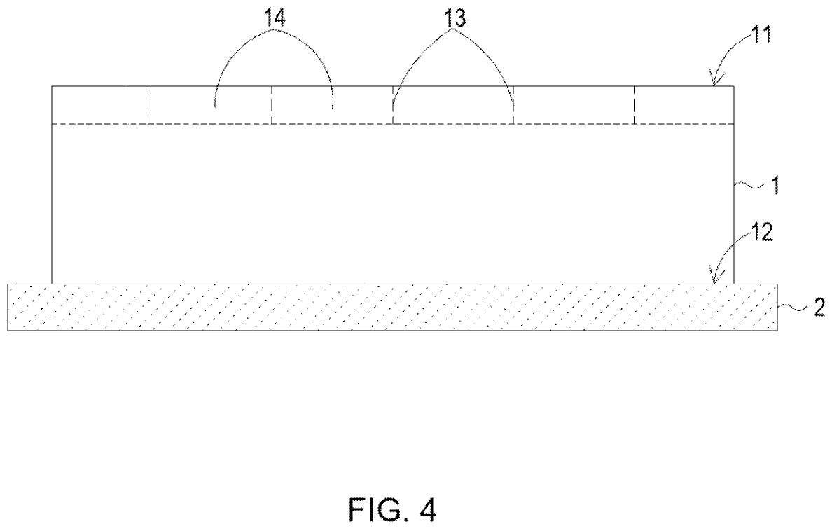

Please refer to FIG. 1, FIG. 2, FIG. 3, and FIG. 4. FIG. 1 schematically illustrates a flowchart of a manufacturing method of a semiconductor according to an embodiment of the present invention. FIG. 2 schematically illustrates a semiconductor substrate, a back protection film, and the cutting of the semiconductor substrate in a manufacturing method of a semiconductor according to an embodiment of the present invention. FIG. 3 schematically illustrates a perspective view of cutting a semiconductor substrate attached with a back protection film and scribing lines and dies in a manufacturing method of a semiconductor according to an embodiment of the present invention. FIG. 4 schematically illustrates a semiconductor substrate, scribing lines, dies, and a back protection film in a manufacturing method of a semiconductor according to an embodiment of the present invention.

As shown in FIG. 1, FIG. 2, FIG. 3, and FIG. 4, according to an embodiment of the present invention, a manufacturing method of a semiconductor includes steps as follows. First of all, as shown in step S10, a semiconductor substrate 1 having a front side 11 and a back side 12 is provided. Next, as shown in step S20, a back protection film 2 is adhered on the back side 12 of the semiconductor substrate 1. Then, as shown in step S30, the semiconductor substrate 1 is cut to a set depth d along a plurality of cutting paths from the front side 11 to form a plurality of scribing lines 13, and a plurality of dies 14 are separated by the scribing lines 13.

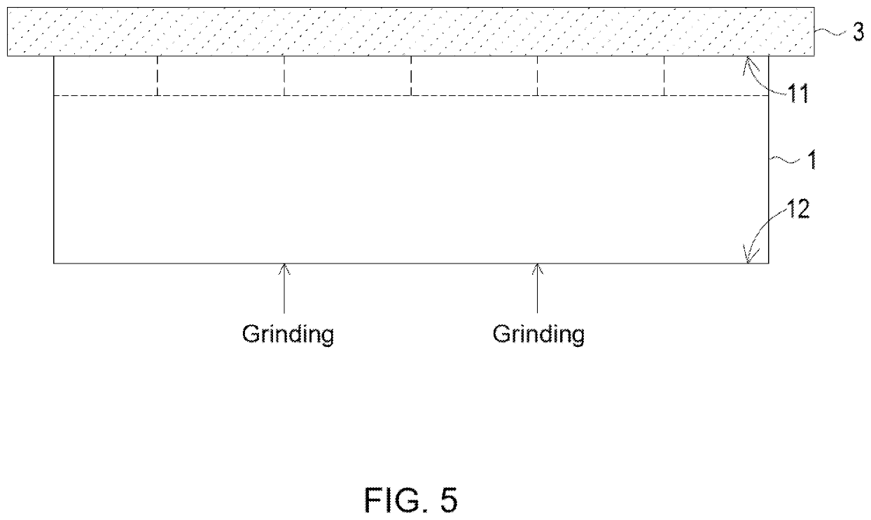

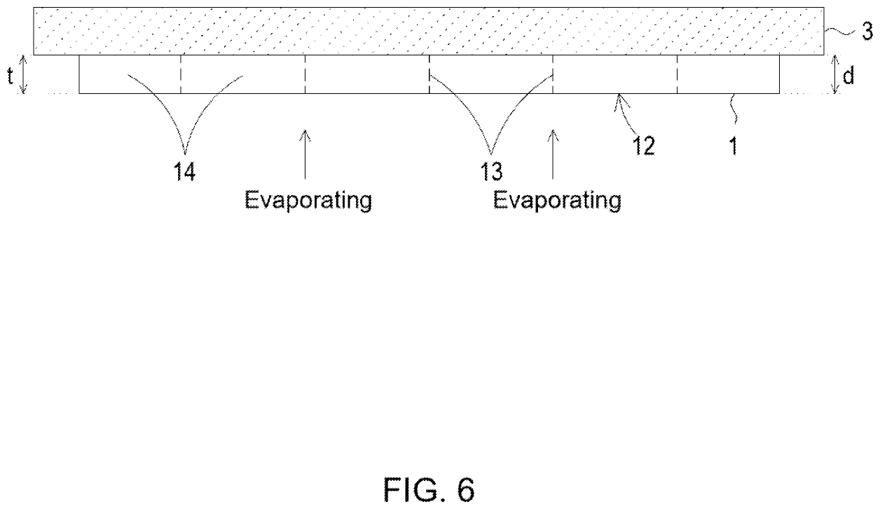

Next, please refer to FIG. 1, FIG. 5, and FIG. 6. FIG. 5 schematically illustrates a front protection film, a semiconductor substrate, and the grinding of the semiconductor substrate from a back side in a manufacturing method of a semiconductor according to an embodiment of the present invention. FIG. 6 schematically illustrates a front protection film, a remaining thickness of the semiconductor substrate equal to a set depth, and the evaporation of the semiconductor substrate from a back side in a manufacturing method of a semiconductor according to an embodiment of the present invention.

As shown in FIG. 1, FIG. 5, and FIG. 6, in step S40 of the manufacturing method of a semiconductor of the present invention, a front protection film 3 is adhered on the front side 11 of the semiconductor substrate 1. Then, as shown in step S50, the back protection film 2 is removed. Next, as shown in step S60, the semiconductor substrate 1 is grinded from the back side 12 until a remaining thickness t of the semiconductor substrate 1 equals to the set depth d, thereby exposing the dies 14 and the scribing lines 13. Then, as shown in step S70, an evaporation is performed to the semiconductor substrate 1, such that a plurality of metal particles are attached to the dies 14.

Please refer to FIGS. 1-6 again. Compared with the technology of prior art, the manufacturing method of a semiconductor of the present invention have several advantages. By adhering a back protection film 2 on a back side 12 of a semiconductor substrate 1 and cutting the semiconductor substrate 1 to a set depth d from a front side 11 firstly, and then adhering a front protection film 3 on the front side 11 of the semiconductor substrate 1 and grinding the semiconductor substrate 1 from the back side 12, the back side 12 of the semiconductor substrate 1 is protected from the risk of breaking during cutting. It also prevents the warpage of the semiconductor substrate 1. Further, by exposing the dies 14 and the scribing lines 13 and performing an evaporation, the metal particles are deeply distributed in the scribing lines 13 and attached around the dies 14. The efficiency of heat-dissipation can be effectively increased.

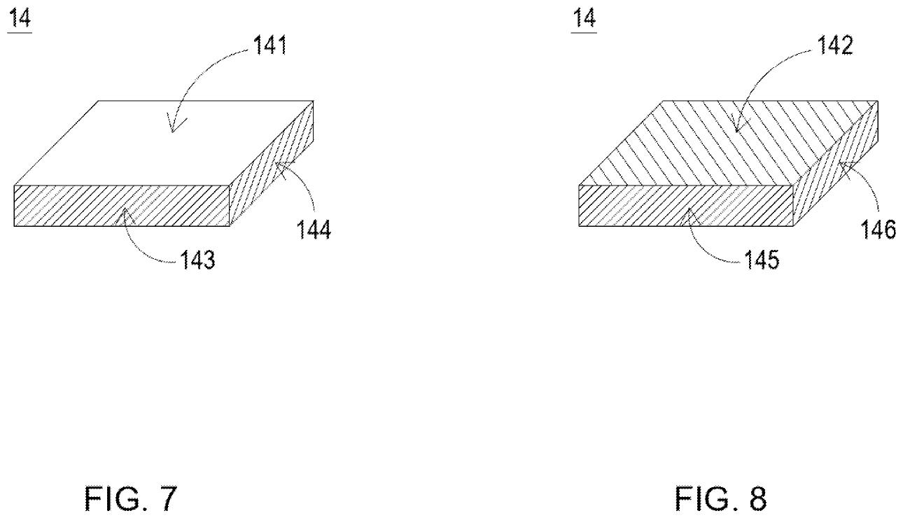

More specifically, please refer to FIG. 7 and FIG. 8. FIG. 7 schematically illustrates a perspective view of a die and the distribution of metal particles after the evaporation of a manufacturing method of a semiconductor according to an embodiment of the present invention. FIG. 8 schematically illustrates an inverted perspective view of the die shown in FIG. 7 and the distribution of metal particles. As shown in FIG. 7 and FIG. 8, each of the dies 14, which are evaporated by the manufacturing method of a semiconductor of the present invention, includes a first surface 141 and a second surface 142 disposed opposite to each other and a third surface 143, a fourth surface 144, a fifth surface 145, and a sixth surface 146 perpendicular to the first surface 141 and the second surface 142, and the metal particles (indicated by diagonal meshes in FIG. 7 and FIG. 8) are attached on the second surface 142, the third surface 143, the fourth surface 144, the fifth surface 145, and the sixth surface 146. In some embodiments, the metal particles may be a plurality of titanium-nickel-silver particles, but not limited thereto.

In other words, since the semiconductor substrate 1 is cut to the set depth d in the step S30 and then grinded from the back side 12 until the remaining thickness t equals to the set depth d in the step S60 of the manufacturing method of a semiconductor of the present invention, i.e., the semiconductor substrate 1 is grinded until the cut portions are grinded through, all of the scribing lines 13 and the dies 14 are exposed. In the subsequent evaporation, the scribing lines 13 are open to the evaporated metal particles, so the metal particles will be attached on not only the second surface 142 of the die 14 (which is the side close to the back side 12 of the semiconductor substrate 1) but also the third surface 143, the fourth surface 144, the fifth surface 145, and the sixth surface 146 of the die 14. Because the first surface 141 of the die 14 is adhered with the front protection film 3, the metal particles will not be attached on the first surface 141 of the die 14.

Compared with the technology of prior art, which only coated metal particles on the back side of the semiconductor substrate or the back side of the die, the manufacturing method of a semiconductor of the present invention utilizes the evaporation to implement attaching metal particles to the bottom surface and four side surfaces of the die, which greatly increases the surface area of the distributed metal particles in comparison with the technology of prior art, and therefore significantly improves the efficiency of heat-dissipation.

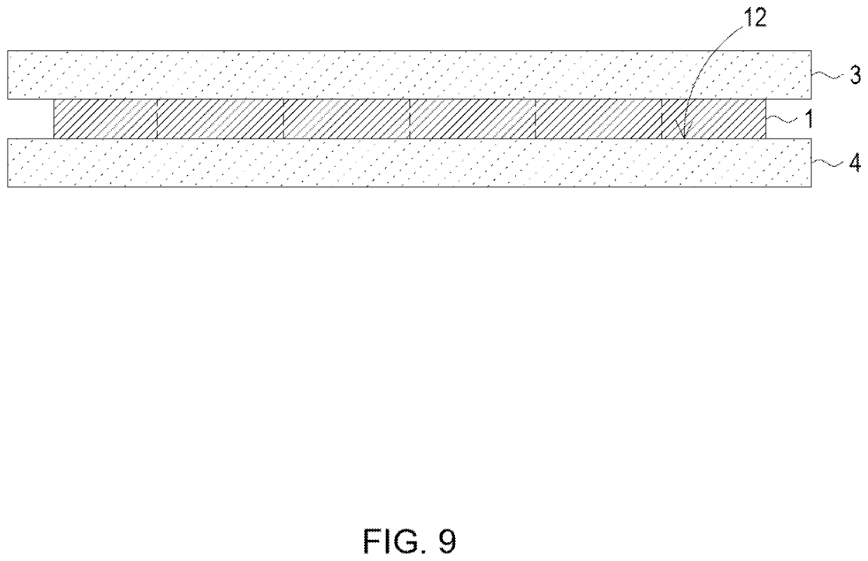

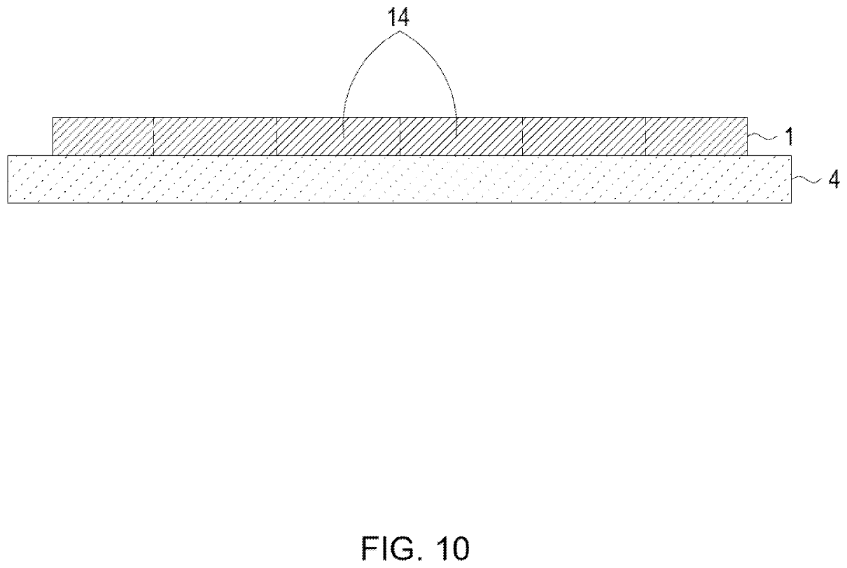

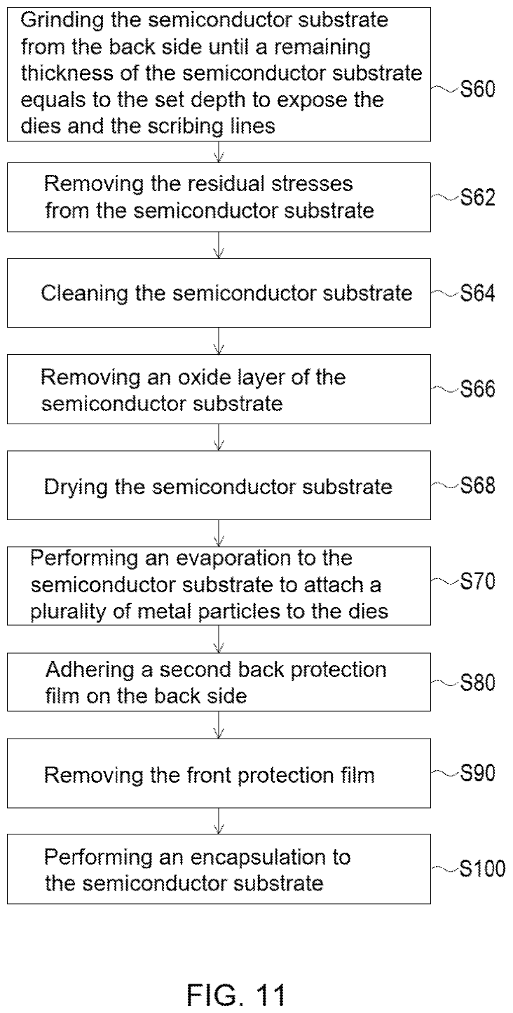

Please refer to FIG. 9, FIG. 10, and FIG. 11. FIG. 9 schematically illustrates a front protection film, a semiconductor substrate, and a second back protection film in a manufacturing method of a semiconductor according to an embodiment of the present invention. FIG. 10 schematically illustrates a semiconductor substrate and a second back protection film in a manufacturing method of a semiconductor according to an embodiment of the present invention. FIG. 11 schematically illustrates a detailed flowchart of a manufacturing method of a semiconductor according to an embodiment of the present invention. As shown in FIGS. 9-11, according to an embodiment of the present invention, a manufacturing method of a semiconductor further includes steps after the step S70 as follows. As shown in step S80, a second back protection film 4 is adhered on the back side 12. Next, as shown in step S90, the front protection film 3 is removed. Then, as shown in step S100, an encapsulation is performed to the semiconductor substrate 1. In some embodiments, the dies 14 can be encapsulated to form a plurality of power chips in the step S100, but not limited thereto.

In addition, between the step S60 and the step S70 of the manufacturing method of a semiconductor of the present invention, the manufacturing method may further include steps S62, S64, S66, and S68. After the step S60 is finished, the residual stresses are removed from the semiconductor substrate 1 in the step S62, for example being implemented by a mixed acid solution. Next, the semiconductor substrate 1 is cleaned in the step S64, for example by deionized water. Then, an oxide layer of the semiconductor substrate 1 is removed in the step S66, for example by hydrofluoric acid. Next, the semiconductor substrate 1 is dried in the step S68, so that the semiconductor substrate 1 is adapted for being performed the evaporation process (i.e., the step S70).

Please refer to FIG. 1 and FIG. 11 again. In some embodiments, the steps S20, S40, and S80 of the manufacturing method of a semiconductor of the present invention are preferably implemented by a film adhering machine, the step S30 is preferably implemented by a wafer cutting machine, the steps S50 and S90 are preferably implemented by a film peeling machine, the step S60 is preferably implemented by a grinding machine, the step S70 is preferably implemented by an evaporating machine, and the step S100 is preferably implemented by encapsulating and testing equipment, but not limited thereto.

Please refer to FIGS. 2-6 again. According to the embodiments of the present invention, the set depth d and the remaining thickness t of the manufacturing method of a semiconductor of the present invention may be in a range between 37.5 μm and 150 μm, i.e., in a range between 1.5 mil to 6 mil, and may be preferably in a range between 50 μm and 100 μm, i.e., preferably in a range between 2 mil to 4 mil, and may be specifically 50 μm, 60 μm, 70 μm, or 80 μm. It should be noted that the practical values of the set depth d and the remaining thickness t can be set and adjusted to meet the practical demands of the products and are not limited to the given examples.

In the embodiments shown in FIGS. 2-10, the set depth d and the remaining thickness t are equal to 70 μm, the width of each scribing line 13 is about 40 μm, and the particle diameter of each metal particle is about 1 μm for example. When the front processes of the semiconductor substrate 1 have been completed and the thickness of the semiconductor substrate 1 is 300 μm and the selected thickness of the back protection film 2 is 90 μm, i.e., the total thickness of the semiconductor substrate 1 and the back protection film 2 is 390 μm, the set depth d (i.e., the desired cutting depth) equal to 70 μm can be implemented by setting a blade height parameter of a blade of the wafer cutting machine selected in the manufacturing method of a semiconductor of the present invention to 320 μm. When the semiconductor substrate 1 is grinded to the remaining thickness t equal to 70 μm, the plurality of scribing lines 13 and the plurality of dies 14 are exposed. Since the width of the scribing lines 13 is about 40 μm, it is easy for the metal particles having a particle diameter about 1 μm to be deeply distributed in the scribing lines 13 and uniformly attached on the four side surfaces of the die 14. Therefore, the bottom surface and the four side surfaces of each die 14 are evenly distributed with metal particles, thereby facilitating heat-dissipation.

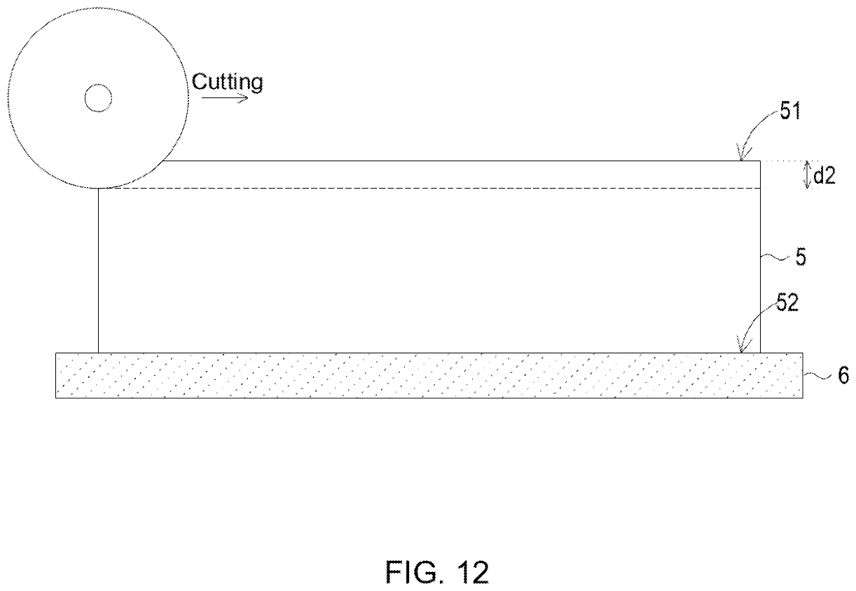

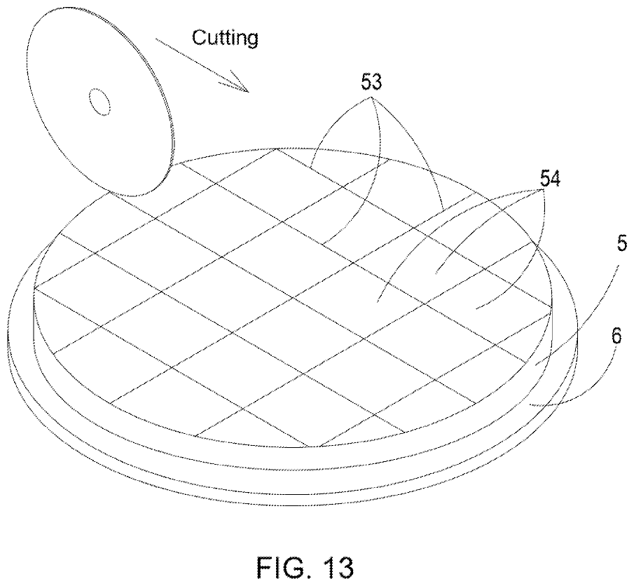

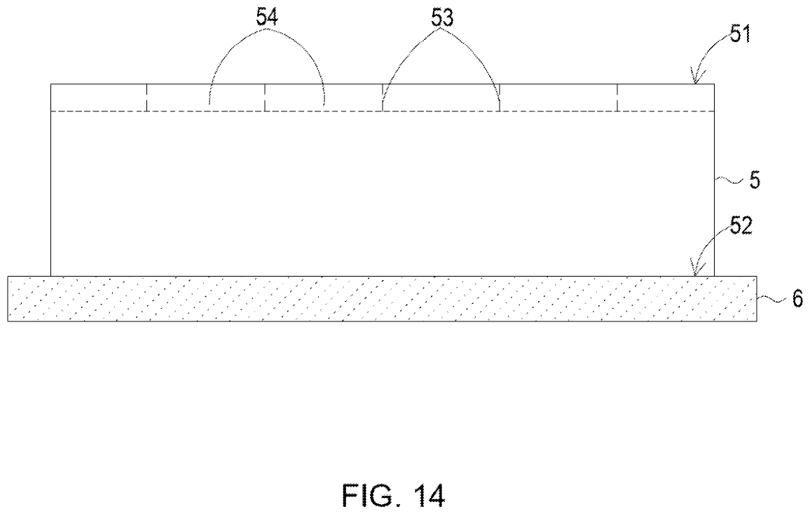

Please refer to FIG. 1, FIG. 12, FIG. 13, and FIG. 14. FIG. 12 schematically illustrates a semiconductor substrate, a back protection film, and the cutting of the semiconductor substrate in a manufacturing method of a semiconductor according to another embodiment of the present invention. FIG. 13 schematically illustrates a perspective view of cutting a semiconductor substrate attached with a back protection film and scribing lines and dies in a manufacturing method of a semiconductor according to another embodiment of the present invention. FIG. 14 schematically illustrates a semiconductor substrate, scribing lines, dies, and a back protection film in a manufacturing method of a semiconductor according to another embodiment of the present invention.

As shown in FIG. 1 and FIGS. 12-14, according to another embodiment of the present invention, a manufacturing method of a semiconductor includes steps as follows. First of all, as shown in step 10, a semiconductor substrate 5 having a front side 51 and a back side 52 is provided. Next, as shown in step S20, a back protection film 6 is adhered on the back side 52 of the semiconductor substrate 5. Then, as shown in step S30, the semiconductor substrate 5 is cut to a set depth d2 along a plurality of cutting paths from the front side 51 to form a plurality of scribing lines 53, and a plurality of dies 54 are separated by the scribing lines 53.

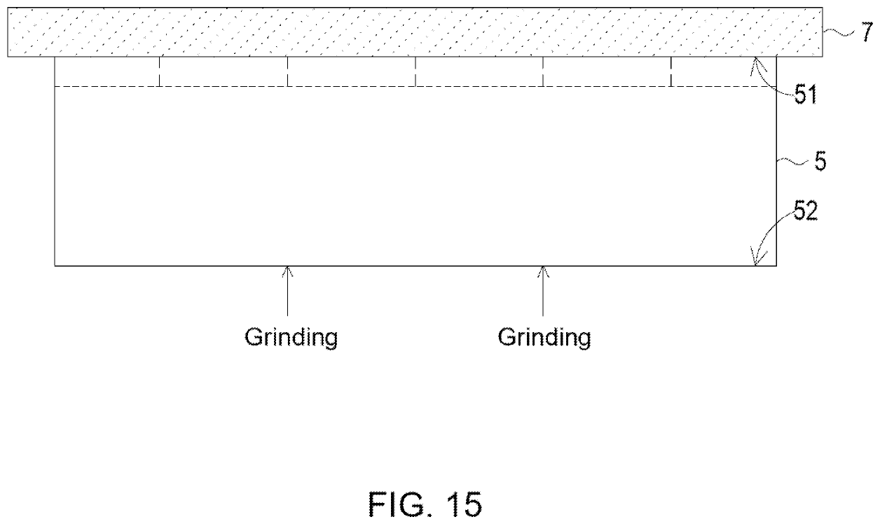

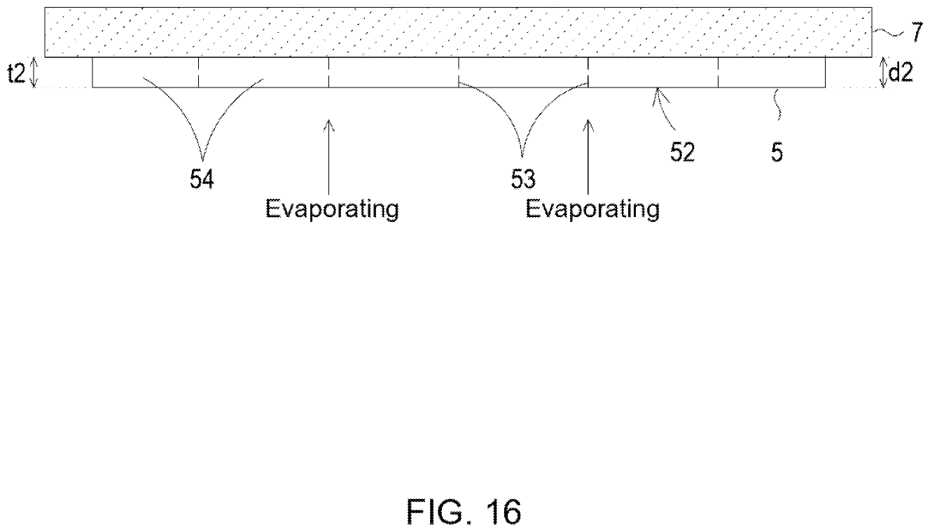

Next, please refer to FIG. 1, FIG. 15, and FIG. 16. FIG. 15 schematically illustrates a front protection film, a semiconductor substrate, and the grinding of the semiconductor substrate from a back side in a manufacturing method of a semiconductor according to another embodiment of the present invention. FIG. 16 schematically illustrates a front protection film, a remaining thickness of the semiconductor substrate equal to a set depth, and the evaporation of the semiconductor substrate from a back side in a manufacturing method of a semiconductor according to another embodiment of the present invention. In step S40 of the manufacturing method of a semiconductor of the present invention, a front protection film 7 is adhered on the front side 51 of the semiconductor substrate 5. Then, as shown in step S50, the back protection film 6 is removed. Next, as shown in step S60, the semiconductor substrate 5 is grinded from the back side 52 until a remaining thickness t2 of the semiconductor substrate 5 equals to the set depth d2, thereby exposing the dies 54 and the scribing lines 53. Then, as shown in step S70, an evaporation is performed to the semiconductor substrate 5, such that a plurality of metal particles are attached to the dies 54.

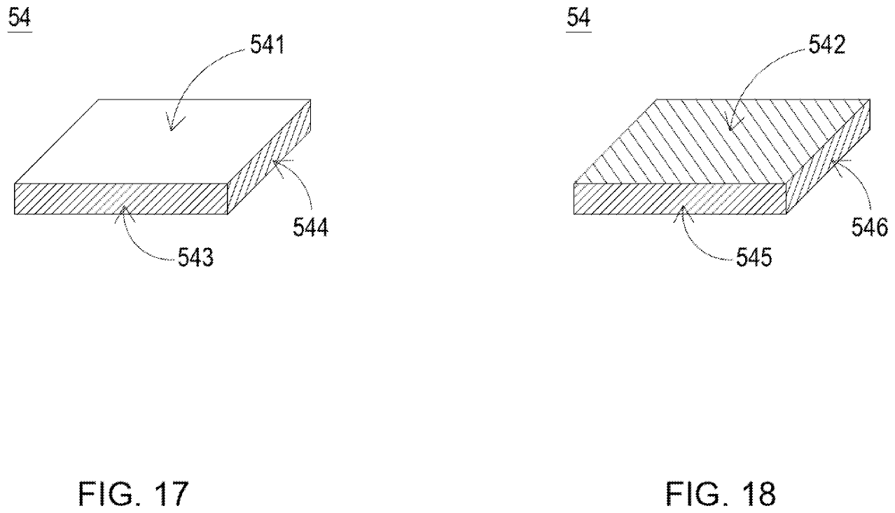

Please refer to FIG. 17 and FIG. 18. FIG. 17 schematically illustrates a perspective view of a die and the distribution of metal particles after the evaporation of a manufacturing method of a semiconductor according to another embodiment of the present invention. FIG. 18 schematically illustrates an inverted perspective view of the die shown in FIG. 17 and the distribution of metal particles. As shown in FIG. 17 and FIG. 18, each of the dies 54, which are evaporated by the manufacturing method of a semiconductor of the present invention, includes a first surface 541 and a second surface 542 disposed opposite to each other and a third surface 543, a fourth surface 544, a fifth surface 545, and a sixth surface 546 perpendicular to the first surface 541 and the second surface 542, and the metal particles (indicated by diagonal meshes in FIG. 17 and FIG. 18) are attached on the second surface 542, the third surface 543, the fourth surface 544, the fifth surface 545, and the sixth surface 546. In some embodiments, the metal particles may be a plurality of titanium-nickel-silver particles, but not limited thereto.

In other words, since the semiconductor substrate 5 is cut to the set depth d2 in the step S30 and then grinded from the back side 52 until the remaining thickness t2 equals to the set depth d2 in the step S60 of the manufacturing method of a semiconductor of the present invention, i.e., the semiconductor substrate 5 is grinded until the cut portions are grinded through, all of the scribing lines 53 and the dies 54 are exposed. In the subsequent evaporation, the scribing lines 53 are open to the evaporated metal particles, so the metal particles will be attached on not only the second surface 542 of the die 54 (which is the side close to the back side 52 of the semiconductor substrate 5) but also the third surface 543, the fourth surface 544, the fifth surface 545, and the sixth surface 546 of the die 54. Because the first surface 541 of the die 54 is adhered with the front protection film 7, the metal particles will not be attached on the first surface 541 of the die 54.

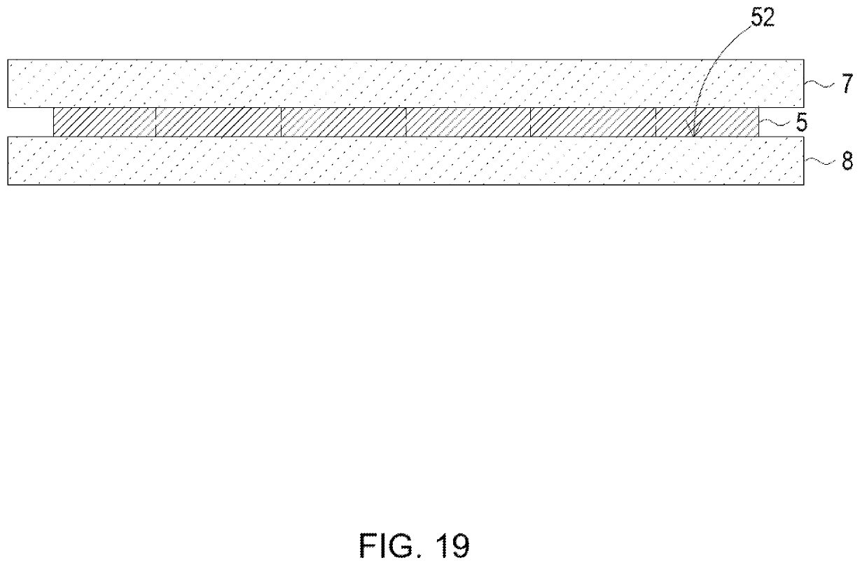

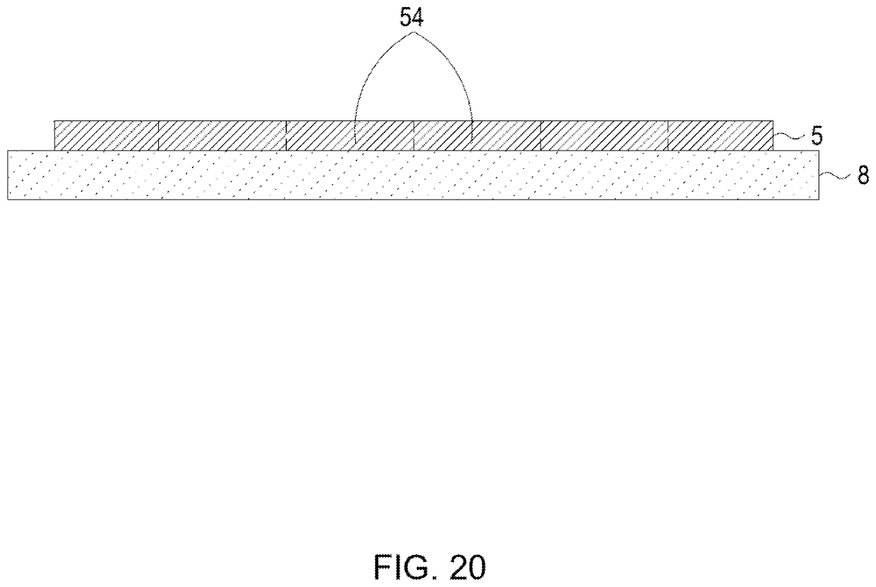

Please refer to FIG. 11, FIG. 19, and FIG. 20. FIG. 19 schematically illustrates a front protection film, a semiconductor substrate, and a second back protection film in a manufacturing method of a semiconductor according to another embodiment of the present invention. FIG. 20 schematically illustrates a semiconductor substrate and a second back protection film in a manufacturing method of a semiconductor according to another embodiment of the present invention. As shown in FIG. 11, FIG. 19, and FIG. 20, according to another embodiment of the present invention, a manufacturing method of a semiconductor further includes steps after the step S70 as follows. As shown in step S80, a second back protection film 8 is adhered on the back side 52. Next, as shown in step S90, the front protection film 7 is removed. Then, as shown in step S100, an encapsulation is performed to the semiconductor substrate 5. In some embodiments, the dies 54 can be encapsulated to form a plurality of power chips in the step S100, but not limited thereto.

In the embodiments shown in FIGS. 12-20, the set depth d2 and the remaining thickness t2 are equal to 50 μm, the width of each scribing line 53 is about 40 μm, and the particle diameter of each metal particle is about 1 μm for example. When the front processes of the semiconductor substrate 5 have been completed and the thickness of the semiconductor substrate 5 is 300 μm and the selected thickness of the back protection film 6 is 90 μm, i.e., the total thickness of the semiconductor substrate 5 and the back protection film 6 is 390 μm, the set depth d2 (i.e., the desired cutting depth) equal to 50 μm can be implemented by setting a blade height parameter of a blade of the wafer cutting machine selected in the manufacturing method of a semiconductor of the present invention to 340 μm. When the semiconductor substrate 5 is grinded to the remaining thickness t2 equal to 50 μm, the plurality of scribing lines 53 and the plurality of dies 54 are exposed. Since the width of the scribing lines 53 is about 40 μm, it is easy for the metal particles having a particle diameter about 1 μm to be deeply distributed in the scribing lines 53 and uniformly attached on the four side surfaces of the die 54. Therefore, the bottom surface and the four side surfaces of each die 54 are evenly distributed with metal particles, thereby facilitating heat-dissipation.

From the above discussion, the present invention provides a manufacturing method of a semiconductor. By adhering a back protection film on a back side of a semiconductor substrate and cutting the semiconductor substrate to a set depth from a front side firstly, and then adhering a front protection film on the front side of the semiconductor substrate and grinding the semiconductor substrate from the back side, the back side of the semiconductor substrate is protected from the risk of breaking during cutting. It also prevents the warpage of the semiconductor substrate. Further, by exposing the dies and the scribing lines and performing an evaporation, the metal particles are deeply distributed in the scribing lines and attached around the dies. The efficiency of heat-dissipation can be effectively increased.

Although the present invention has been disclosed by way of preferred embodiments, it is not intended to limit the present invention. A person having ordinary skill in the art may make various changes and modifications without departing from the spirit and scope of the invention. The protection scope of the present invention is intended to be limited only by the appended claims.

What is claimed is:

1. A manufacturing method of a semiconductor, comprising steps of:
(a) providing a semiconductor substrate having a front side and a back side;
(b) adhering a back protection film on the back side;
(c) cutting the semiconductor substrate to a set depth along a plurality of cutting paths from the front side to form a plurality of scribing lines and separate a plurality of dies by the scribing lines;
(d) adhering a front protection film on the front side;
(e) removing the back protection film;
(f) grinding the semiconductor substrate from the back side until a remaining thickness of the semiconductor substrate equals to the set depth to expose the dies and the scribing lines; and
(g) performing an evaporation to the semiconductor substrate to attach a plurality of metal particles to the dies.

2. The manufacturing method of a semiconductor as claimed in claim 1, wherein each of the dies comprises a first surface and a second surface disposed opposite to each other and a third surface, a fourth surface, a fifth surface, and a sixth surface perpendicular to the first surface and the second surface, and the metal particles are attached on the second surface, the third surface, the fourth surface, the fifth surface, and the sixth surface.

3. The manufacturing method of a semiconductor as claimed in claim 1, wherein the metal particles are a plurality of titanium-nickel-silver particles.

4. The manufacturing method of a semiconductor as claimed in claim 1, wherein the set depth is in a range between 37.5 μm and 150 μm.

5. The manufacturing method of a semiconductor as claimed in claim 1, wherein the scribing lines each has a width equal to 40 μm, and the metal particles each has a particle diameter equal to 1 μm.

6. The manufacturing method of a semiconductor as claimed in claim 1, wherein a thickness of the back protection film is 90 μm, and in the step (c), a thickness of the semiconductor substrate is 300 μm.

7. The manufacturing method of a semiconductor as claimed in claim 6, wherein the set depth is 70 μm, the step (c) is implemented by a blade of a wafer cutting machine, and a blade height parameter of the blade is 320 μm.

8. The manufacturing method of a semiconductor as claimed in claim 1 further comprising steps, between the step (f) and step (g), of:
(f1) removing residual stresses from the semiconductor substrate;
(f2) cleaning the semiconductor substrate;
(f3) removing an oxide layer of the semiconductor substrate; and
(f4) drying the semiconductor substrate.

9. The manufacturing method of a semiconductor as claimed in claim 1 further comprising steps, after the step (g), of:
(h) adhering a second back protection film on the back side;
(i) removing the front protection film; and
(j) performing an encapsulation to the semiconductor substrate.

10. The manufacturing method of a semiconductor as claimed in claim 9, wherein in the step (j), the dies are encapsulated to form a plurality of power chips.
